(19) United States
(12) Patent Application Publication
(10) Pub. No.: US 2006/0186795 A1
(43) Pub. Date: Aug. 24, 2006

(54) Organic electroluminescent display and fabricating method thereof

(75) Inventor: Chun-Yi Chiu, Taoyuan City (TW)

Correspondence Address: BACON & THOMAS, PLLC, 625 SLATERS LANE, FOURTH FLOOR, ALEXANDRIA, VA, 22314, US

(73) Assignee: AU OPTRONICS CORP., Hsin-Chu (TW)

(21) Appl. No.: 11/216,048

(22) Filed: Sep. 1, 2005

(30) Foreign Application Priority Data
Feb. 23, 2005 (TW) 94105497

(51) Int. Cl. H01J 1/62; H01J 63/04

(52) U.S. Cl. 313/504

(57) ABSTRACT

The invention achieves the above-identified object by providing an organic electroluminescent display (OELD) comprising a display panel and a cover glass. The cover glass is made of a tempered glass and fabricated on the display panel.

This application claims the benefit of Taiwan Application Serial No. 094105497, filed Feb. 23, 2005, the subject matter of which is incorporated herein by reference.

### BACKGROUND OF THE INVENTION

1. Field of the Invention

The invention relates in general to an organic electroluminescent display (OELD) and a fabricating method thereof, and more particularly to a OELD with a tempered glass as a cover glass and a fabricating method thereof.

2. Description of the Related Art

Organic electroluminescent devices have been popularly applied to various flat displays because such advantages of self-emissive, very thin form factor, high luminance, high luminous efficiency, high contrast, fast response time, wide viewing angle, low power consumption, wide temperature operation range, and potential of flexible substrate.

The organic material and the metal electrode in the OELD are subject to react with water vapor. It has a bad influence on the display quality and the lifetime of the OELD. Conventionally, a drier is disposed in the recess of the cover, and the cover and the display panel are assembled to produce an OELD. The cover is usually made of either metal or glass. The strength of the metallic cover is greater than that of the glass, because the glass is sandblasted to a recess to accommodate the drier.

However, the metallic cover has poor adherence to the substrate made of glass. Also, the metallic cover expands more than the glass does when it is heated, so that the metal-glass interface is subject to stress problem. Besides, the metallic cover of large size is not only expensive and deformed easily. Further, the strength of the conventional cover glass sandblasted to form the recess has been deteriorated. The electronic device having such cover glass is easily broken when falling, especially the portable electronic device, such as camera and mobile phone.

### SUMMARY OF THE INVENTION

In view of the foregoing, it is an object of the present invention to provide an organic electroluminescent display (OELD) and fabricating method thereof capable of being shock-proof, and having great adherence to the display panel. The cover is made of tempered glass which can resist four to five times impact than conventional one.

The invention achieves the above-identified object by providing an organic electroluminescent display (OELD) comprising a display panel and a cover glass. The cover glass is made of a tempered glass, and fabricated on the display panel.

It is another object of the invention to provide a method for fabricating an organic electroluminescent device, comprising steps of: (a). providing a display; (b). providing a tempered glass as a cover glass; (c). assembling the display panel and the cover glass.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a perspective view of the organic electroluminesecent display according to the preferred embodiment of the present invention.

FIG. 2 is a flow chart showing a method for fabricating the organic electroluminescent display according to the preferred embodiment of the present invention.

FIG. 3A illustrates the UV glue-applying process according to the preferred embodiment of the invention.

FIG. 3B is a top side view of the cover glass of FIG. 3A after the UV glue is applied thereon.

FIG. 4 is a plot showing the relation between the concentration of Potassium ions in the cover glass and the flatness.

FIG. 5 schematically illustrates the method for testing the strength of the cover glass.

FIG. 6A is a plot showing the strength-comparison of the sandblasted side between the Soda glass and the cover glass according to preferred embodiment of the present invention.

FIG. 6B is a plot showing the strength-comparison of the non-sandblasted side between the Soda glass and the cover glass according to preferred embodiment of the present invention.

### DETAILED DESCRIPTION OF THE INVENTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

In view of the foregoing, it is an object of the present invention to provide an organic electroluminescent display (OELD) and the fabricating method thereof. This OELD of the invention comprises a display panel and a cover glass fabricated thereon. The cover glass is made of a tempered glass, also called toughened glass, to prevent from cracking when falling.

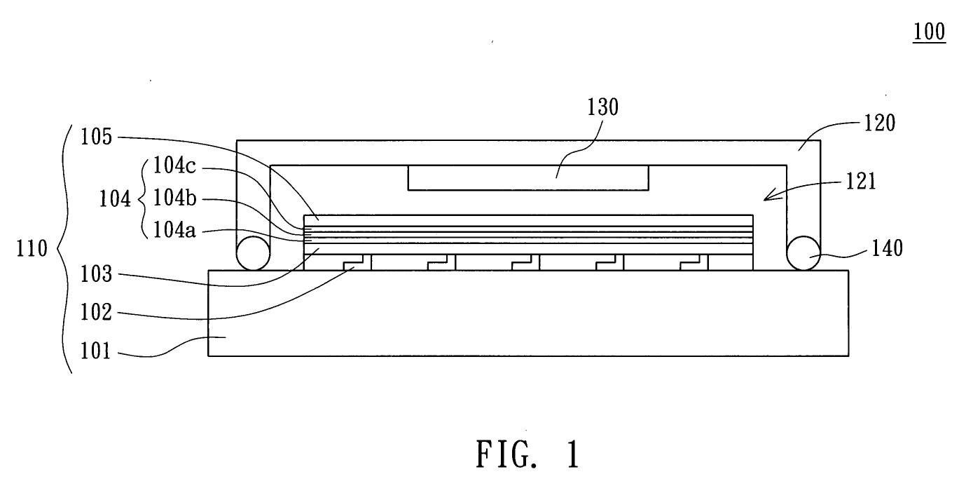

Referring to FIG. 1, it is a perspective view of the organic electroluminsecent display according to the preferred embodiment of the present invention. The organic electroluminescent display (OELD) 100 of the invention includes a display panel 110, a cover glass 120, a drier 130, and an adhesive 140.

The display panel 110 includes a substrate 101, a thin film transistor (TFT) 102, an anode 103, an organic electroluminescent structure 104, and a cathode 105. The anode 103 is formed on the substrate 101, and the TFT 102 is formed between the anode 103 and the substrate 101′. The cathode 105 is formed on the organic electroluminescent structure 104. Preferably, the organic eletroluminescent structure 104 includes a hole transport layer (HTL) 104a, an emission layer (EL) 104b, and an electron transport layer (ETL) 104c. The HTL 104a is formed on the anode 103; the EL 104b is formed on the HTL 104a; the ETL 104b is formed on the EL 104c. It is noted that the anode 103 and the cathode 105 are formed relatively, so that the anode and the cathode are not limited thereto.

The cover glass 120 is made of tempered glass, and preferably is a chemically-treated Soda glass having a Potassium ion concentration of more than 1%. The cover glass 120 has a recess 121 facing the display panel, and the drier 130 is disposed in the recess 121. The adhesive 140, such as UV glue, for adhering the cover glass 120 onto the display panel 110. It contributes a hermetically sealed space. Preferably, the hermetically sealed space is filled with nitrogen.

The cover glass 120 is the treated Soda glass, in which the concentration of Potassium ions (K⁺) is higher than the concentration of the Sodium ions (Na⁺). The Potassium ion concentration of the cover glass is between about 3% and about 10%. Preferably, the concentration of Potassium ions (K⁺) in the cover glass is about 5.5%.

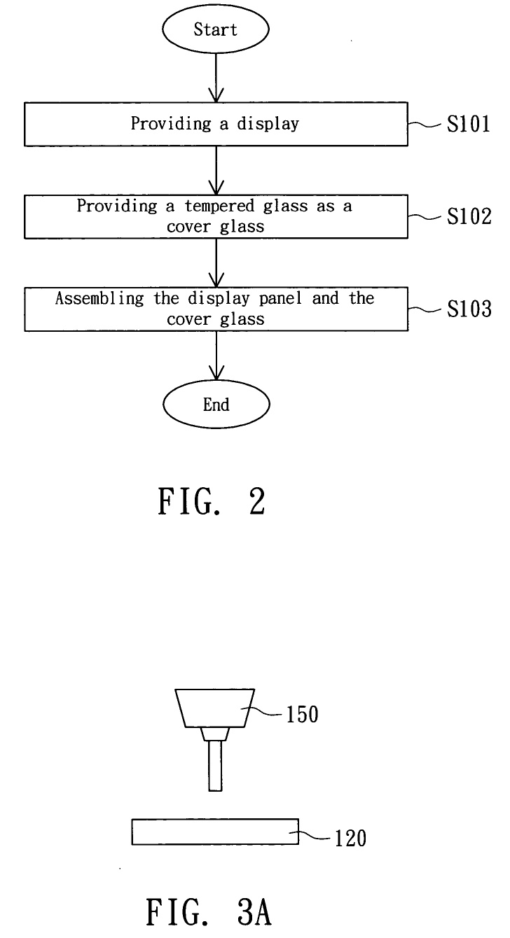

Referring to FIG. 2, it is a flow chart showing a method for fabricating the organic electroluminescent display according to the preferred embodiment of the present invention. The method for fabricating the OELD includes several steps S101-S103; providing a display panel; providing a tempered glass as a cover glass; and assembling the display panel and the cover glass.

First, in the step S101, a display panel 110 is provided. Next, in the step S102, a tempered glass is provided as a cover glass 120. The step S102 includes several steps as follow. First, a piece of general Soda glass, whose concentration of Potassium ions (K⁺) is typically lower than 1%, is provided. The size of the Soda glass, for example, is 370 mm×470 mm. Then, the Soda glass is sandblasted to form several recesses 121. The area of the recess 121 is substantially equal to the area of the display screen. If six recesses are formed on the Soda glass, the Soda glass will be cut into six pieces to provide six cover glasses. Finally, the Soda glass is immersed into a solution containing Potassium ions (K⁺) to be transformed into a tempered glass. The enforcing step preferably proceeds in the high thermal condition to accelerate the Sodium(Na⁺)-Potassium(K⁺) ion exchange between the Soda glass and the solution. The solution containing Potassium ions (K⁺) is preferably a molten Potassium salt. The Sodium ions on the surface of the Soda glass are replaced by Potassium ions whose atomic radius is bigger than Sodium ions to generate a compress stress on the surface of the cover glass 120, so that it can increase the cover glass's resistance of the shock. In general, the higher the concentration of Potassium ions (K⁺) in the treated Soda glass, the more compress stress the cover glass owns, and the greater strike the cover glass could bear. Besides, the enforcing reaction only happens on the surface of the glass, so the enforced glass, as so called tempered glass, could still undergo further process, such as drilling, cutting, and coating. Moreover, the tempered glass can resist heat up to 200˜250° C.

Through changing the concentration of Potassium ions, temperature, and immersion time, the concentration of Potassium ions replacing Sodium ions on the surface of the cover glass can be designed. Preferably, the concentration of Potassium ions in the solution is between about 40 g/cm³ and about 80 g/cm³. The concentration of Potassium ions in the cover glass enforcing by the solution stated below is between about 3% and about 10%, and preferably is about 5.5%.

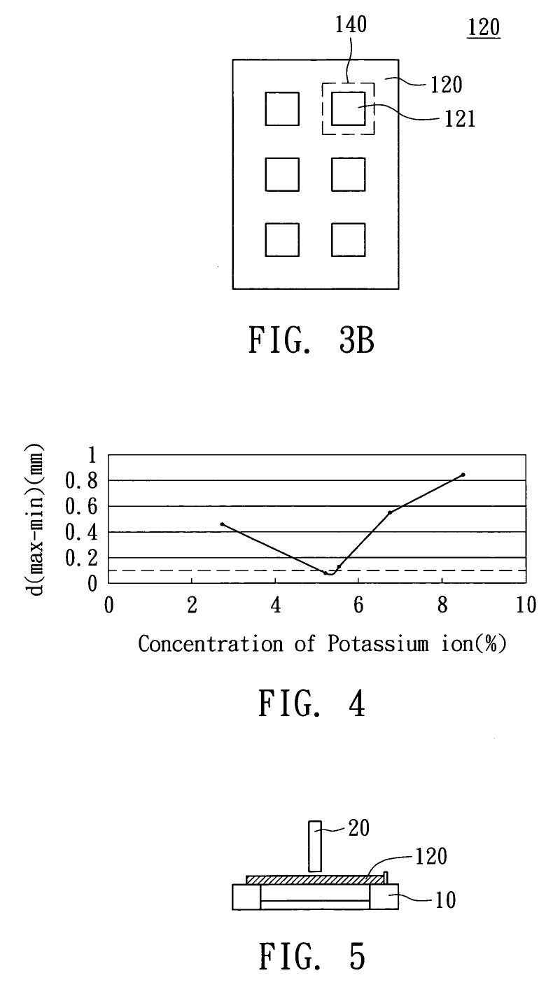

Then, in the step S103, the display panel 110 and the cover glass 120 are assembled. The step S103 includes several steps as follow. First, the drier 130 is disposed in the recess 121, and UV glue is applied to the cover glass 120. Referring to FIG. 3A and 3B, FIG. 3A illustrates the UV glue-applying process according to the preferred embodiment of the invention, and FIG. 3B is a top side view of the cover glass of FIG. 3A after the UV glue is applied thereon. For example, a glue applier 150 is set above the cover glass 120, and spaced at a distance as shown in FIG. 3A. Then, the UV glue 140 is dropped on the cover glass 120 along the border of the recess 121 by the glue applier 150 which moves along the designed track. Next, the display panel 110 is combined with the cover glass 120. Finally, the UV glue 140 is cured by irradiating UV light, so that the cover glass 120 and the display panel 110 are assembled. After the assembled display panel and the cover glass undergoes several module processes, such as scribing, breaking, IC bonding process, a plurality of OELD can be fabricated completely.

Some result of the experiments are listed below to analyze the flatness and the strength of the cover glass in the OELD fabricating according to the method stated above.

Experiment One—Test of Flatness

The flatness of the cover glass influences the amount of the glue applied on the cover glass, that is closely linked to the yield. If the cover glass is not flat, the distance between the glue applier, which is set at the pre-determinated position, and the cover glass will be variable, so that the glue amount of every point on the cover glass is not even. It has a bad influence on the yield.

The method of testing the flatness of the cover glass includes several steps stated below. Some point on the cover glass is chosen randomly. When the glue applier passes through the chosen point, the distance between the cover glass and the glue applier is measured and recorded. Then, the maximum subtracts the minimum to obtain a difference as a standard to estimate the flatness. In this test, the cover glasses with different concentration of Potassium ions are tested, and the results are presented as the plot.

Referring to FIG. 4, it is a plot showing the relation between the concentration of Potassium ions in the cover glass and the flatness. When the concentration of Potassium ions in the cover glass is between 3%˜8%, the difference of distance existed in the glue applier and the cover glass is between about 0.1 mm and about 0.8 mm. It is noted that when the concentration of Potassium ions in the cover glass is substantially 5.5%, the difference of distance existed in the glue applier and the cover glass is about 0.1 mm. Thus, the cover glass having a Potassium ion concentration of about 5.5% is so flat that suitably applied in the manufacture process can improve the yield. As a result, the concentration of Potassium ions in the cover glass of the preferred embodiment is between 3% and 10%. Preferably, the concentration of Potassium ions is about 5.5%.

Experiment Two—Test of Strength

Referring to FIG. 5, it schematically illustrates the method for testing the strength of the cover glass. The method of testing the strength of the cover glass includes some steps stated below. First, a tested object is put in the base 10, and the tested side faces upwards. Then, a pre-determinated force is applied on the tested side by the machine 20. The pre-determinated force applied on the tested side increases until the tested object is broken, so the force breaking the tested object is then defined as the strength of the tested object.

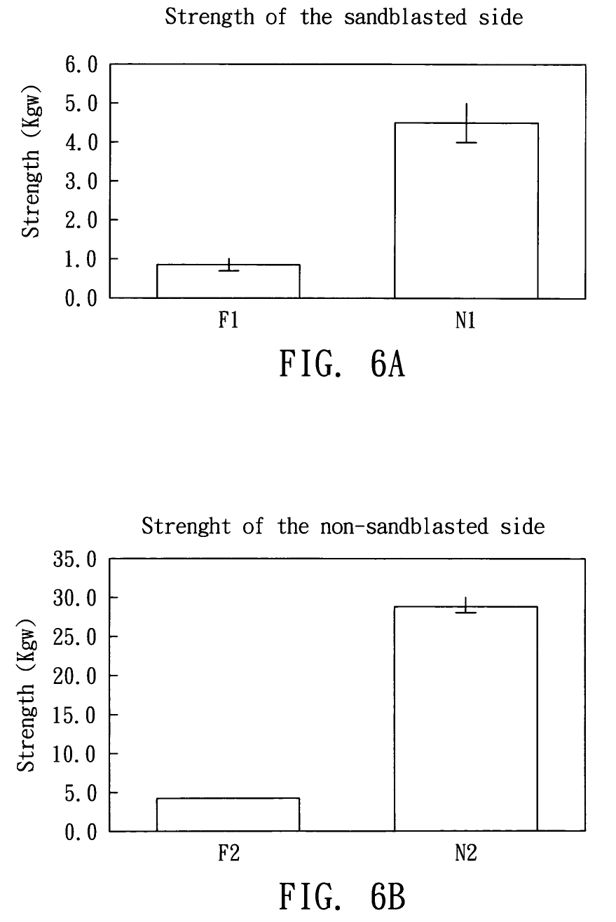

The cover glass, whose concentration of Potassium ions is 5.5%, is provided in this test. The cover glass fabricated by the method stated above is compared with the Soda glass, and the sandblasted side and non-sandblasted side are considered respectively. Referring to FIG. 6A and 6B, FIG. 6A is a plot showing the strength-comparison of the sandblasted side between the Soda glass and the cover glass according to preferred embodiment of the present invention, and FIG. 6B is a plot showing the strength-comparison of the non-sandblasted side between the Soda glass and the cover glass according to preferred embodiment of the present invention. As shown in the FIG. 6A, the greatest force that the sandblasted side of conventional Soda glass F1 could bear is 0.76 kgw. The greatest force that the sandblasted side of cover glass N1 according to preferred embodiment of the present invention could bear is 4.375 kgw, and it is 5.8 times more than that conventional Soda glass N1 could.

As shown in FIG. 6B, the greatest force that the non-sandblasted side of conventional Soda glass F2 could bear is 4.319 kgw. The greatest force that the non-sandblasted side of cover glass N2 according to preferred embodiment of the present invention could bear is 27.974 kgw, and it is 6.4 times more than that conventional Soda glass N2 could. To sum up, the cover glass fabricated by the method according to the preferred embodiment of the present invention can tolerate four to five times impact more than conventional one can.

As described hereinbefore, the organic electroluminescent display and fabricating method thereof has many advantages. First, the cover glass of the present invention can bear four to five times impact than conventional one can. It allows to increase the strength of the OELD, and to reduce the broken opportunity when falling. Then, the cover glass with characteristic of flatness could directly apply to the present fabricating process of OELD. It allows to uniform the amount of the glue applied on the cover glass, and to raise the yield.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An organic electroluminescent display (OELD), comprising:
a display panel; and
a cover glass made of a tempered glass and fabricated on the display panel.

2. The OELD according to claim 1, wherein the concentration of Potassium ions (K⁺) in the cover glass is higher than the concentration of Sodium ions (Na⁺).

3. The OELD according to claim 1, wherein the cover glass has a Potassium ion concentration of more than 1%.

4. The OELD according to claim 1, wherein the tempered glass is a chemically-treated Soda glass.

5. The OELD according to claim 1, wherein the concentration of Potassium ions in the cover glass is between about 3% and about 10%.

6. The OELD according to claim 1, wherein the concentration of Potassium ions in the cover glass is about 5.5%.

7. The OELD according to claim 1, wherein the cover glass has a recess facing the display panel.

8. The OELD according to claim 7, further comprising a drier disposed in the recess.

9. The OELD according to claim 1, further comprising an adhesive for adhering the display panel to the cover glass to form a hermetically sealed space.

10. The OELD according to claim 9, wherein the hermetically sealed space is filled with nitrogen.

11. The OELD according to claim 9, wherein the adhesive is UV glue.

12. The OELD according to claim 1, wherein the display panel comprises:
a substrate;
an anode formed on the substrate;
an organic eletroluminescent structure, formed on the anode, the organic electroluminesecnt structure comprising:
a hole transport layer (HTL), formed on the anode;
a emission layer (EL), formed on the HTL; and
a electron transport layer, formed on the EL; and
a cathode formed on the organic eletroluminescent structure.

13. The OELD according to claim 12, the display panel further comprising a thin film transistor (TFT) formed between the substrate and the anode.

14. A method of fabricating an organic electroluminescent device, comprising steps of:
providing a display;
providing a tempered glass as a cover glass; and
assembling the display panel and the cover glass.

15. The method according to claim 14, wherein the step of providing the tempered glass as a cover glass comprises:
providing a soda glass;
sandblasting the soda glass to form a recess; and
immersing the soda glass in a solution containing Potassium ions to form a tempered glass.

16. The method according to claim 15, wherein the concentration of the Potassium ions in the solution is between about 40 g/cm³ and about 80 g/cm³.

17. The method according to claim 15, wherein the step of assembling the display panel and the cover glass comprises:
disposing a drier in the recess;
applying UV glue to the cover glass;
combining the display panel with the cover glass;
curing the UV glue with UV light, so that the cover glass is connected to the display panel.

18. The method according to claim 14, wherein the concentration of the Potassium ions (K⁺) is higher than the concentration of Sodium ions (Na⁺).

19. The method according to claim 14, wherein the tempered glass is a chemically-treated Soda glass having a Potassium ion concentration of more than 1%.

20. The method according to claim 14, wherein the concentration of Potassium ions in the cover glass is between about 3% and about 10%.

21. The method according to claim 14, wherein the concentration of Potassium ions in the cover glass is about 5.5%.
